(19) United States
(12) Patent Application Publication
(10) Pub. No.: US 2026/0024564 A1
(43) Pub. Date: Jan. 22, 2026

(54) MEMORY INTERFACE CONTROLLER

(71) Applicant: Infineon Technologies LLC, San Jose, CA (US)

(72) Inventors: Amir Rochman, Tel-Aviv (IL); Yoram Betser, Mazkeret-Batya (IL); Kobi Danon, Tel-Aviv (IL); Ron Varkony, Netanya (IL)

(73) Assignee: Infineon Technologies LLC, San Jose, CA (US)

(21) Appl. No.: 18/774,665

(22) Filed: Jul. 16, 2024

(51) Int. Cl. G11C 7/22; G11C 7/10

(52) U.S. Cl. CPC G11C 7/222; G11C 7/1036; G11C 7/1069

(57) ABSTRACT

In accordance with an embodiment, a circuit, includes: a plurality of per-read memory controllers, each of the plurality of per-read memory controllers configured to output a set of read operation signals based on a dynamically selected divided clock signal of a plurality of divided clock signals, wherein each divided clock signal of the plurality of divided clock signals has a different phase; a memory controller selection circuit configured to sequentially select a per-read memory controller from the plurality of per-read memory controllers for a single read operation, wherein a selected per-read memory controller in a first read operation is different from a selected per-read memory controller in a subsequent read operation; and an output combining circuit coupled to outputs of the plurality of per-read memory controllers.

### TECHNICAL FIELD

The present invention relates generally to an electronic system, and, in particular embodiments, to a memory interface controller.

### BACKGROUND

In a typical flash memory system, data is stored in an array of memory cells, organized into pages and blocks. To access a specific memory location, the corresponding block and page addresses are provided to a memory controller. The memory controller then activates the appropriate page and block, allowing the data to be read from or written to the selected memory cells. However, this process can be time-consuming, especially when dealing with large amounts of data and other accompanying functions such as read calculations an error correction code handling.

To address this limitation, parallel processing of read commands can be employed. By enabling multiple memory read commands to be processed simultaneously, the overall throughput of the memory system can be significantly increased. This way, data can be read from multiple banks in parallel, and memory read and data output operations can be performed in parallel between different reads. Parallel processing allows for more efficient utilization of memory resources.

However, the parallel processing of read commands presents several technical challenges, including increased power consumption, complex control logic, and data synchronization issues. As the number of parallel read operations increases, the power required to operate the memory system also rises, which can lead to thermal and power management difficulties. Additionally, implementing parallel processing requires more sophisticated control logic within the memory controller to manage the simultaneous execution of multiple read commands. Ensuring proper synchronization and coordination among the parallel operations to maintain data integrity and prevent conflicts becomes a challenging technical issue.

### SUMMARY

In accordance with an embodiment, a circuit, includes: a plurality of per-read memory controllers, each of the plurality of per-read memory controllers configured to output a set of read operation signals based on a dynamically selected divided clock signal of a plurality of divided clock signals, wherein each divided clock signal of the plurality of divided clock signals has a different phase; a memory controller selection circuit configured to sequentially select a per-read memory controller from the plurality of per-read memory controllers for a single read operation, wherein a selected per-read memory controller in a first read operation is different from a selected per-read memory controller in a subsequent read operation; and an output combining circuit coupled to outputs of the plurality of per-read memory controllers.

In accordance with another embodiment, a method of operating a memory includes; selecting a per-read memory controller from a plurality of per-read memory controllers for a single read operation wherein a selected per-read memory controller in a first read operation is different from a selected per-read memory controller in an immediately subsequent read operation; and outputting a set of read operation signals by the selected per-read memory controller, the set of read operation signals being timed according to a dynamically selected clock signal of a plurality of divided clock signals.

In accordance with a further embodiment, a system, includes: a memory array; a memory interface configured to be coupled to a memory bus; a clock divider having an input coupled to a clock signal input of the memory interface and outputs configured to provide a plurality of divided clock signals having different phases; a clock enable circuit configured to receive a selection signal from the memory interface and assert one of a plurality of enable signals corresponding to one of the plurality of the divided clock signals having a phase corresponding to the received selection signal; a plurality of per-read memory controllers having data inputs coupled to the memory interface, clock inputs coupled to outputs of the clock divider, and enable inputs coupled to the plurality of enable signals, each of the plurality of per-read memory controllers configured to output a set of read operation signals based on data provided to the memory interface, wherein the set of read operation signals is timed according to the one of the plurality of divided clock signals having the phase corresponding to the received selection signals; a memory controller selection circuit configured to sequentially select a per-read memory controller from the plurality of per-read memory controllers for a single read operation, wherein a selected per-read memory controller in a first read operation is different from a selected per-read memory controller in a subsequent read operation; and a combining circuit having inputs coupled to outputs of the plurality of per-read memory controllers, and an output coupled to the memory array.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1A is a timing diagram illustrating the relationship between multiple read commands and a user clock and divided clock signals in a memory interface system, according to some implementations;

FIG. 1B is a block diagram of a memory integrated circuit system, according to some implementations; FIG. 1C is a timing diagram for a memory controller's read operation process for a single per-read memory channel, according to some implementations; and FIG. 1D is a timing diagram showing how multiple instances of per-read memory controllers interact with each other, according to some implementations.

FIG. 2A is a block diagram of a counter select circuit within a memory controller system, according to some implementations; FIG. 2B is a block diagram of a per-read memory controller, according to some implementations; FIG. 2C is a block diagram of a clock selection circuit, according to some implementations; FIG. 2D is another block diagram of a control signal selection circuit, according to some implementations; FIG. 2E is a block diagram of a clock enable circuit within a memory controller system, according to some implementations; and FIG. 2F is a block diagram of a control circuit according to some implementations;

FIG. 3 is a flowchart of a method according to some implementations; and

FIGS. 4A and 4B illustrate block diagrams of memory systems according to embodiments.

Corresponding numerals and symbols in different figures generally refer to corresponding parts unless otherwise indicated. The figures are drawn to clearly illustrate the relevant aspects of the preferred embodiments and are not necessarily drawn to scale. To more clearly illustrate certain embodiments, a letter indicating variations of the same structure, material, or process step may follow a figure number.

### DETAILED DESCRIPTION OF ILLUSTRATIVE EMBODIMENTS

The making and using of the presently preferred embodiments are discussed in detail below. It should be appreciated, however, that the present invention provides many applicable inventive concepts that can be embodied in a wide variety of specific contexts. The specific embodiments discussed are merely illustrative of specific ways to make and use the invention and do not limit the scope of the invention.

Some embodiments relate to a memory controller configured to manage multiple parallel read operations in high-speed and random-access memory interfaces, including but not limited to LPDDR4.

In an embodiment, a memory controller includes a set of per-read memory controllers (also referred to as “counters”) that are each configured to handle a single read operation from start to finish. During operation, an incoming read command is dynamically assigned a per-read memory controller and dynamically assigned a divided clock having a phase that corresponds to the incoming read command. The assigned per-read memory controller may wait a predetermined latency time and then start generating internal data and control signals for controlling a memory array to perform the requested memory read. Successive incoming read commands are assigned respective per-read memory controllers and divided clocks in a similar manner to enable parallel operation. Once each per-read memory controller completes its assigned read operation, its output is disabled and is made ready for its next dynamic assignment.

Advantages of some embodiments include the ability to handle multiple reads in parallel without needing multiple controllers that are statically assigned to each divided clock, which may result in more efficient use of die size and lower power consumption. Moreover, the dynamic assignment of controllers results in only a small part of the controller being active when a small number of reads are being performed in parallel, which also saves power. In some embodiments, each per-read memory controller may be further configured to produce signals that support error correction and redundancy features, such as error correction code (ECC) address trapping, column redundancy replacement, GNG flow, and support for internal register reads. Advantages also include the ability to store control and command signals during a latency time, and then output the signals when necessary. In some embodiments, this ability to store and then output control and command signals is achieved in a more space efficient manner than a pipeline implementation. A further advantage includes the ability to effectively manage the assignment and usage of multiple divided clocks.

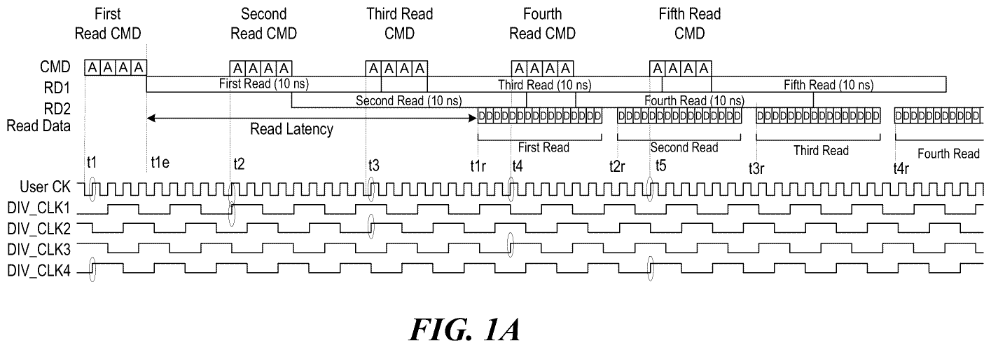

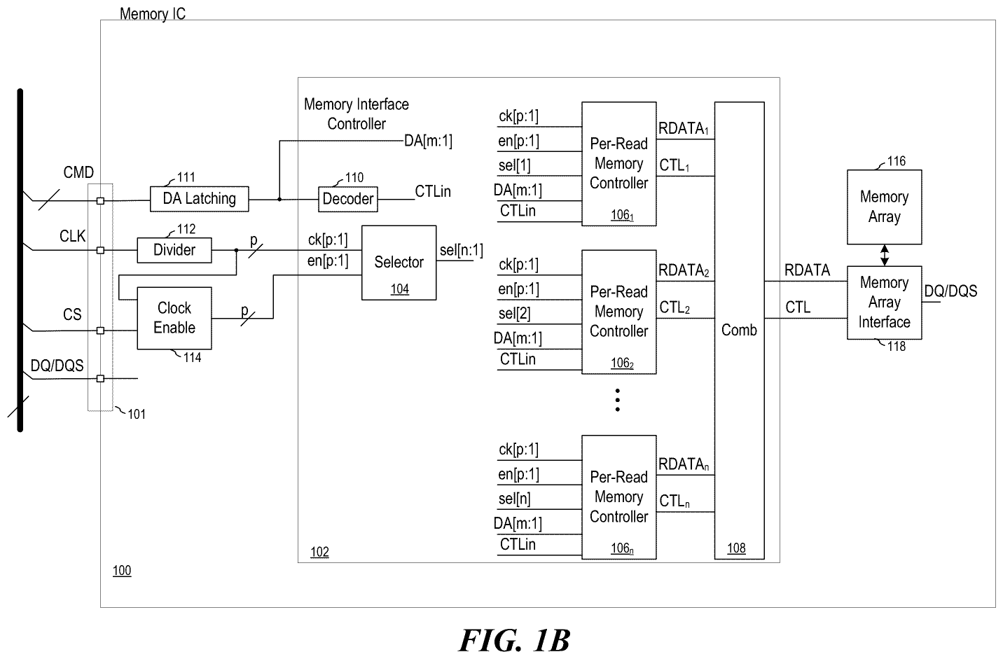

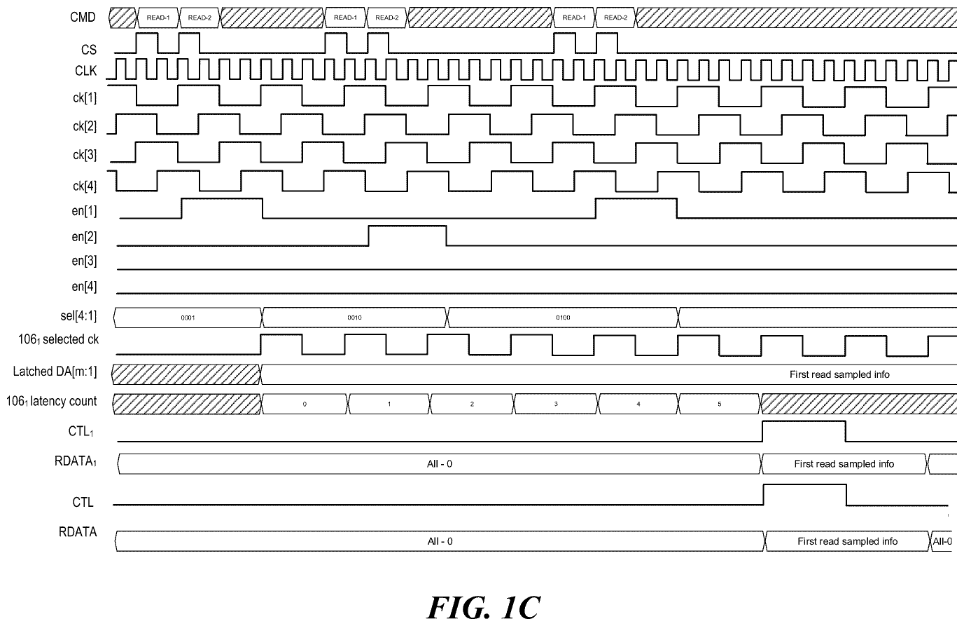

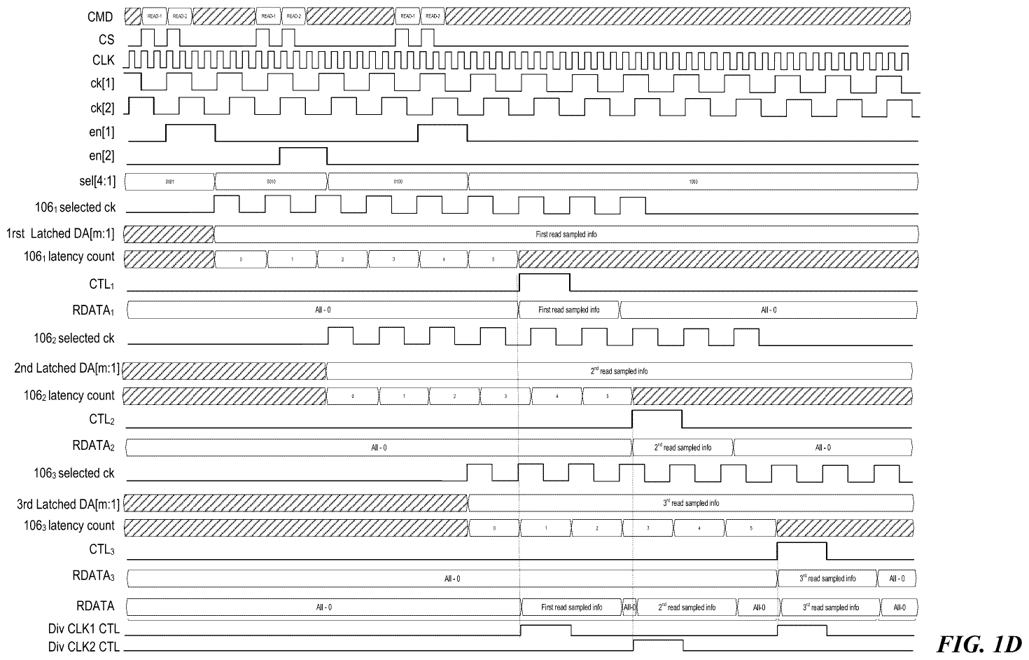

FIG. 1A depicts an exemplary timing diagram illustrating the relationship between multiple read commands with a user clock and divided clock signals in a memory interface system, which can be used as an aid in understanding the issue of using a divided clock for processing read commands simultaneously. In the diagram, signal CMD represents a memory command that is applied to a memory interface; signal RD1 represents the operation of a first read from a memory array lasting 10 ns; signal RD2 represents the operation of a second read from the memory array lasting 10 ns; and Read Data represents the requested read data that is produced in response to the read command. In some embodiments, signals RD1 and RD2 represent reads that are performed from different memory banks from the memory array, thereby allowing two or more read operations to overlap in time as shown. The diagram further shows the clock signal provided to the memory interface (User CK) and four divided clock signals of different phases: DIV_CLK1, DIV_CLK2, DIV_CLK3, and DIV_CLK4, derived from User CK.

In the illustrated example, reading activity in response to the read commands is processed simultaneously, for example, in implementations that allow for different memory banks to be read at the same time. For example, a portion of the first read command is processed on memory control channel RD1 at the same time that a first portion of the second read command is processed on memory control channel RD2. Similarly, a portion of the third read command is processed on channel RD1 at the same time that a second portion of the second read command is processed on channel RD2. It can be further seen that the second and third read commands are received during the read latency time of the first read command. This read latency time is shown as being the time between the end of the first read command at time t1e and the time at which the first read data is clocked out of the memory at time t1r.

As shown, the first read command is written to the memory interface prior to the rising edge of the fourth divided clock DIV_CLK4 at time t1. Similarly, the second read command is written to the memory interface prior to the rising edge of the first divided clock DIV_CLK1 at time t2; the third read command is written to the memory interface prior to the rising edge of the second divided clock DIV_CLK2 at time t3; the fourth read command is written to the memory interface prior to the rising edge of the third divided clock DIV_CLK3 at time t4; and the fifth read command is written to the memory interface prior to the rising edge of the fourth divided clock DIV_CLK5 at time t5.

It can be seen that the relationship between the read command and the next divided clock edge is not predetermined and can be random. Read data is produced after a latency time following the end of a command. It should be appreciated that the number of memory control channels RD1 and RD2 may correspond to the number of simultaneously readable memory banks in the memory array. In some embodiments, multiple read channels may simultaneously process a memory read that arrived according to the same divided clock, while at other times multiple read channels may simultaneously process a memory read that arrived according to different clocks. Hence, in an implementation in which RD1 and RD2 are implemented using memory controllers with statically assigned divided clocks, a total of four memory controllers could be used to cover situations in which simultaneously arriving read commands are assigned to any one of DIV_CLK1, DIV_CLK2, DIV_CLK3, or DIV_CLK4 given the timing of the illustrated example.

However, as the number of divided clocks changes, there could be a corresponding change in the number of memory controllers as well.

In an embodiment of the present invention, each incoming read command is dynamically assigned a per-read memory controller for a single read, and is dynamically assigned a divided clock. Such a system may be implemented as shown in FIG. 1B that depicts a block diagram of a memory integrated circuit (IC) system 100 that includes a memory interface controller 102, a memory array 116, a memory array interface 118, a clock divider 112, a clock enable circuit 114, and a data latching circuit 111.

Memory interface controller 102 includes n per-read memory controllers 106 that are configured to generate respective memory read data and control signals RDATAₓ and CTLₓ for a single memory read operation from start to finish based on one of p clock signals ck[p:1] that is dynamically assigned by clock enable circuit 114 according to clock enable signals en[p:1]. (Note: ck[p:1] is a bus nomenclature that specifies “p” separate signals, and the “x” in RDATAₓ and CTLₓ is a variable associated with the particular instance of per read memory controller 106.) In some embodiments, clock enable signals en[p:1] have one bus line active at a time that specifies the corresponding clock signal. Alternatively, en[p:1] could be an encoded signal having the same or different number of signal lines as p.

Memory read information signals and control signals RDATAₓ and CTLₓ (which are also referred to as “read operation signals”) include, for example, data and control signals compatible with the operation of memory array interface 118. This data may include address data, control signals, clock signals, and other signals required by memory array interface 118. In some embodiments, each per-read memory controller 106 may also optionally produce additional signals that support other memory operation features, including but not limited to ECC address trapping, column redundancy replacement, GNG flow and support for internal register reads. For example, in one embodiment, RDATAₓ may represent commands and/or control signals for internal register reads and/or commands or register addresses to support address trapping in case of a read failure detected by on-chip ECC circuitry. In in some embodiments, internal addressing for memory array 116 is handled by other circuitry different from memory interface controller 102 and is not included in RDATAₓ. Alternatively, RDATAₓ may contain an internal address used to access memory array 116. In some embodiments, control signal CTLₓ is used to control and/or activate the output of data from memory 116.

Memory interface controller 102 further includes a memory controller selection circuit 104 that dynamically assigns one of the per-read memory controllers 106 to an incoming read command. In some embodiments, this dynamic assignment is performed by sequentially selecting instances of per-read memory controller 106. As shown, memory controller selection circuit 104 is connected to clock divider 112 and clock enable circuit 114 that are, in turn, coupled to memory interface 101. Memory interface 101 is configured to be coupled to a memory bus having signals chip select CS, user clock CLK, command data CMD, read data, and data/data strobe signals DQ/DQS. In some embodiments, the memory bus may operate in accordance with a predetermined memory protocol, such as LPDDR4 or another protocol.

During operation, memory controller selection circuit 104 provides signal sel[n:1] to indicate a current per-read memory controller selection. In an embodiment, selection signals sel[n:1] include n signals corresponding to each of the n memory per-read controllers. In one example, only one of the selection signals sel[n:1] is asserted at a particular time so that the code 0001 corresponds to the first per-read memory controller 106₁, code 0010 corresponds to the second per-read memory controller 106₂, and so on. In alternative embodiments, the selection signals may be encoded in a different manner using the same or different number of bits.

Output combining circuit 108 aggregates the outputs from multiple per-read memory controllers and sends the combined data to the memory array interface circuit 118 that is responsible for interfacing with memory array 116. In some embodiments, combining circuit 108 could be implemented using one or more OR gates, using one or more multiplexer circuits known in the art, or using a wired OR implementation in which the output of each per-read memory controller is placed in a high impedance state when its outputs are inactive.

In some embodiments, memory interface controller 102 further includes data latching circuit 111 that latches the command signal CMD from memory interface 101, and a command decoder 110 that translates the latched command signal CMD (or a portion of the latched command signal) into a control signal CTLin. Signal CTLin may be a memory read enable signal, a register read enable, signal or other memory related control signal having one or more bits for use by memory array interface 118. A portion of the command signal CMD latched by data latching circuit 111 includes read information data DA[m:1] that contains data for use by memory array interface 118. Read information data DA[m:1] may represent, for example address or other command information for ECC address trapping, column redundancy replacement, GNG flow and internal register reads. Alternatively, read information data DA[m:1] may contain an internal address used to select output from various memory banks in memory array 116, for example, via an internal multiplexer. In some embodiments, decoder 110 may be implemented internally within each per-read memory controller 106.

The clock divider 112 receives the user clock signal CLK at a clock signal input and divides it into multiple phases to produce divided clock signals ck[p:1], such that the divided clock signals ck[p:1] have different phases. Clock divider 112 may be implemented, for example, using known clock divider circuits in the art, for example, using a series of flip-flops arranged in a divider chain or using a synchronous counter.

In various embodiments, some or all of the components of memory IC 100 may be implemented on a single monolithic semiconductor integrated circuit, such as a single semiconductor substrate and/or a silicon substrate. Memory IC 100 may be fabricated using one of a variety of different semiconductor processes, such as CMOS, FinFET, BiCMOS, SOI, or another type of semiconductor process. Memory array 116 may be a volatile memory array, such as DRAM or SRAM, or non-volatile memory array, such as flash memory or EEPROM.

FIG. 1C depicts a timing diagram for a memory controller's read operation process for a single per-read memory controller 106. The trace CMD represents an incoming command, which may include a read command or other commands, such as a write command; trace CS represents a chip select signal, and trace CLK represents the user clock. Signals ck[1], ck[2], ck[3] and ck[4] represent the various divided clocks having different phases, while traces en[1], en[2], en[3] and en[4] represent clock enable signals. Traces sel[4:1] represent the selection signals for per-read memory controllers 106. Latched data DA[m:1] represents a latched version of the read information data DA[m:1] used for a respective single memory read that is latched within its respective per-read memory controller (e.g., per-read memory controller 106₁ for the first channel).

Trace 106₁ latency count represents a latency count produced internally within per-read memory controller 106. CTL₁ represents the control output of per-read memory controller 106₁, and RDATA₁ represents the read information data output by per-read memory controller 106₁. Signals CTL and RDATA respectively represent control data and read information data output by memory interface controller 102 by all per-read memory controllers 106 provided to memory array interface 118. The trace labeled as 106₁ selected clock represents the selected divided clock that is used to clock internal circuitry of the first per-read memory controller 106₁. In some embodiments, the latency count may be programmable and/or configurable, for example, to support configurable read latency for LPDDR4 interfaces. This latency count by be configurable, for example, via an on-chip configuration register.

As shown, select signals sel[4:1] are initially set to 0001, which means that the first per-read memory controller 106₁ is assigned to process the next upcoming read command. Chip select signal CS is asserted along with read commands READ-1 and READ-2 on the command signal lines CMD, and are assigned divided clock ck[1], the rising edge of which corresponds to two cycles of clock signal CLK after the first assertion of chip select signal CS. The corresponding enable signal en[1] is asserted by clock enable circuit 114. Next, the selected clock, 106₁ selected ck, for the first per-read memory controller 106 is activated within the first per-read memory controller 106, initiating a latency count. Enable signal en[1] initiates the corresponding selected clock signal, 106₁ selected ck, and, in conjunction with selection signal sel[1], initiates the latency count as shown with respect to signals 106₁ latency count. The selection signal sel[4:1] then advances from state 0001 to 0010, indicating that the second per-read memory controller 106 is now selected for the next read command for the next subsequent read cycle.

At the expiration of the latency count of the first per-read memory controller 106, control signals CTL₁ and read data output RDATA₁ from the first per-read memory controller 106 are asserted. Signals CTL₁ and RDATA₁ are propagated to the output of output combining circuit 108 for input to memory array controller 118. While the depicted timing diagram shows signals RDATA₁ and CTL₁ being asserted/activated immediately at the expiration of the latency count, in alternative embodiments, the timing of signals RDATA_{1c} and CTL₁ (as well as signals CTL₂ to CTLₙ and RDATA₂ to RDATAₙ) could be different. For example, signals RDATA₁ and/or CTL₁ could be asserted before the expiration of the latency count or sometime after the expiration of the latency count depending on the particular embodiment and is specifications.

FIG. 1D depicts a timing diagram for memory interface 102 that shows how multiple instances of per-read memory controllers 106 interact with each other. The diagram is an expanded view of the timing diagram of FIG. 1C that illustrates the sequence of events that occur during the processing of multiple read commands in memory IC 100. The signals represented on FIG. 1D further include 2^{nd} latched data DA[m:1], which represents read information data internally latched within second per-read memory controller 106₂, trace 106₂ latency count, which represents a latency count produced internally within the second per-read memory controller 106₂, trace 106₂ selected clock, which represents the selected divided clock that is used to clock internal circuitry of the second per-read memory controller 106₂, trace CTL₂, which represents the control output of the second per-read memory controller 106₂, trace RDATA₂, which represents the read information data output for the second per-read memory controller 106₂, 3^{rd} latched data DA[m:1], which represents the read information data internally latched within a third per-read memory controller (not shown), trace 106₃ latency count, which represents a latency count produced internally within the third per-read memory controller, trace 106₃ selected clock, which represents the selected divided clock that is used to clock internal circuitry of the third per-read memory controller, trace CTL₃, which represents the control output of the third per-read memory controller, and trace RDATA₃, which represents the read information data output for the third per-read memory controller 106₃. Trace RDATA represents the ORed outputs of RDATA₁, RDATA₂ RDATA₃ to RDATAₙ for all per-read memory controllers 106, trace Div CLK1 CTL represents the ORed control signals associated with the first divided clock ck[1] for all per-read memory controllers 106, and trace Div CLK2 CTL represents the ORed control signals associated with the second divided clock ck[2] for all per-read memory controllers 106. Divided clock signals ck[3], ck[4] that are unassigned in this example are omitted for simplicity of illustration, as well as their associated ORed control signals Div CLK3 CTL and Div CLK4 CTL.

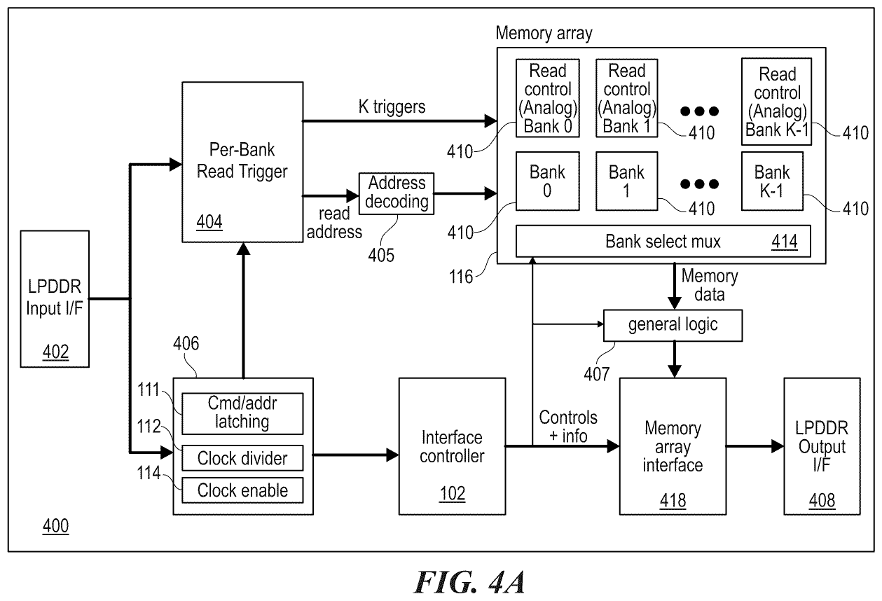

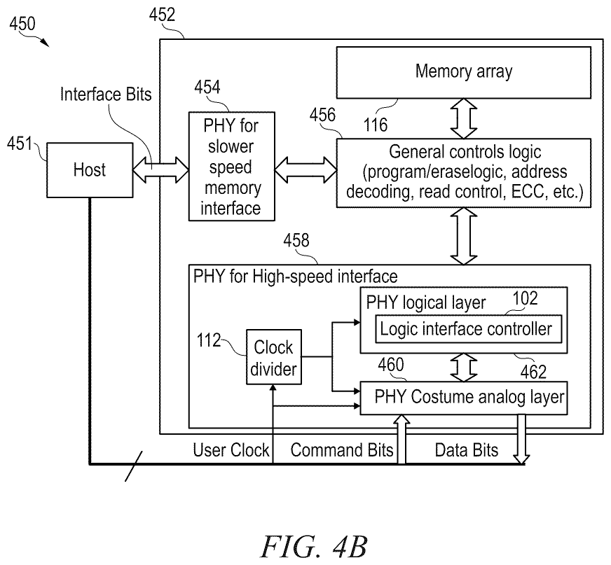

The first read operation for the first per-read memory controller proceeds as discussed above with respect to FIG. 1C. During the latency count of the first per-read memory controller 106₁, per-read memory controller selection signals sel[4:1] advances from state 0001 to 0010, indicating that the second per-read memory controller 106 is now selected for the next read command. During this latency count, data from memory array 116 is outputted to memory array interface 118. Prior to the last clock of 106₁ selected ck used by the first per-read memory controller 106₁, the first read information is removed from read information signal RDATA₁, and all outputs go to zero due to all RDATA outputs from all per-read memory controllers 106 going to zero. Memory data may be provided to the external memory bus via lines DQ in similar manner as shown in FIG. 1A. In embodiments of the present invention each, per-read memory controller 106 keeps their respective CTL and RDATA signals at zero unless the respective per-read memory controller is active and configured asserts its respective CTL and RDATA signals after the expiration of read latency time. In some embodiments, signals CTLₓ and RDATAₓ may also be active earlier while memory array is being read. For example, these signals may be activated in order select a memory band in memory array 116 (e.g. via a multiplexer such as bank select multiplexer 414 shown in FIG. 4A) or to provide control signals in advance for piping purposes.

During the latency count of the first per-read memory controller 106₁ (and prior to the end of the first memory read operation), a second read command may be asserted on the memory interface. However, this time the assertion of the chip select signal CS and command data CMD occurs is associated with divided clock ck[2], which causes the corresponding enable signal en[2] to be asserted by clock enable circuit 114. The signal 106₂ selected clock for the second per-read memory controller 106 is activated within the second per-read memory controller 106, initiating a further latency count, and selection signal sel[4:1] is advanced from state 0010 to 0100, indicating that a third per-read memory controller 106 is selected to process the next command. At the expiration of the 106₂ latency count, which is the latency count of the second per-read memory controller 106₂, control signals CTL₂ and read information data RDATA₂ is provided by second per-read memory controller 106₂.

Operation of the third per-read memory controller proceeds in a similar manner. During the latency count of the second per-read memory controller 106₂ (and prior to the end of the second memory read operation), a third read command may be asserted on the memory interface. However, this time the assertion of the chip select signal CS and command data CMD occurs is again associated with the first divided dock ck[1], which causes the corresponding enable signal en[1] to be asserted by clock enable circuit 114. The signal 106₃ selected clock for the third per-read memory controller is activated within the third per-read memory controller, initiating a further latency count, and selection signal sel[4:1] is advanced from state 0010 to 0100, indicating that a fourth per-read memory controller (not shown) is selected to process the next command. At the expiration of the 106₃ latency count, which is the latency count of the third per-read memory controller, control signals CTL₃ and read information data RDATA₃ is provided by the third per-read memory controller 106.

As shown, trace RDATA represents the ORed outputs of RDATA₁, RDATA₂ and RDATA₃ to RDATAₙ for all per-read memory controllers 106. Trace Div CLK1 CTL representing the ORed control signals associated with the first divided clock includes two control pulses corresponding to the first and third read command, and trace Div CLK3 CTL representing the ORed control signals associated with the second divided clock shows a single pulse corresponding to the second read command that was assigned the second divided clock ck[2].

This sequence of events demonstrates how the memory controller system can manage multiple read operations in parallel, with each per-read memory controller 106 handling a single read operation from start to finish. It should be appreciated that the behavior illustrated in the timing diagrams of FIGS. 1C and 1D is just one example of a single memory circuit operated according to one set of conditions. In alternative embodiments, the number and type of signals present, as well as their corresponding behavior, may be different.

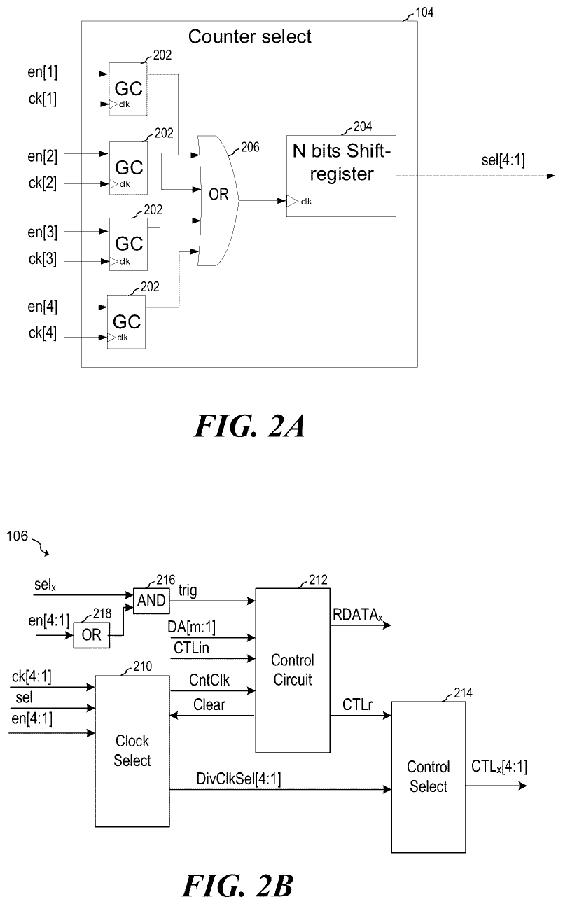

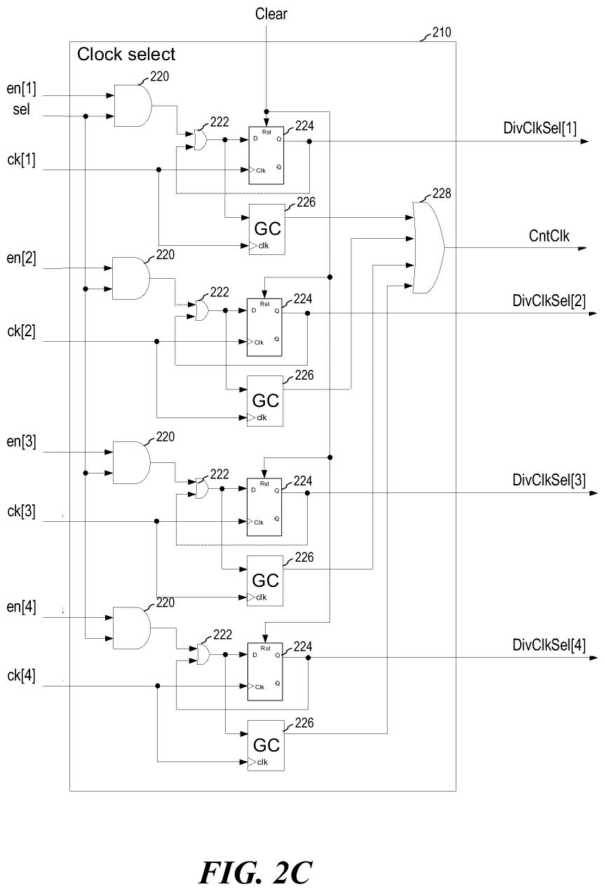

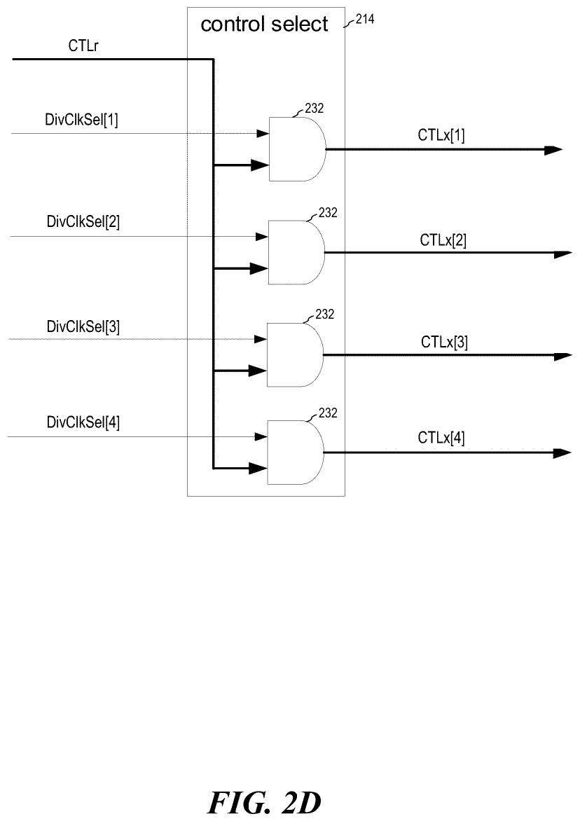

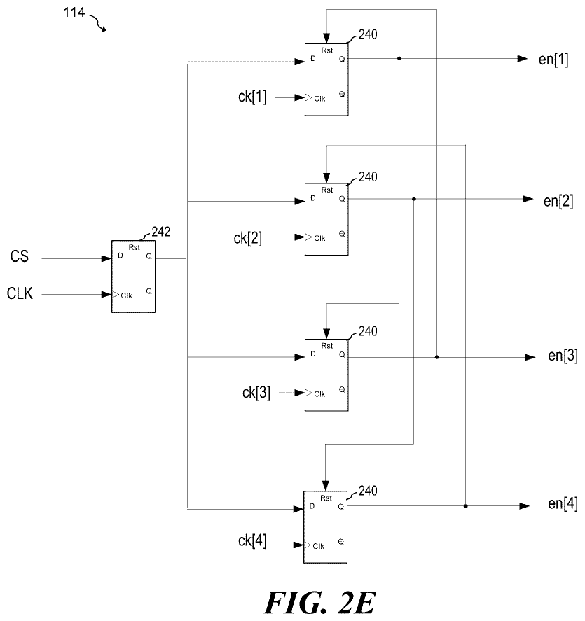

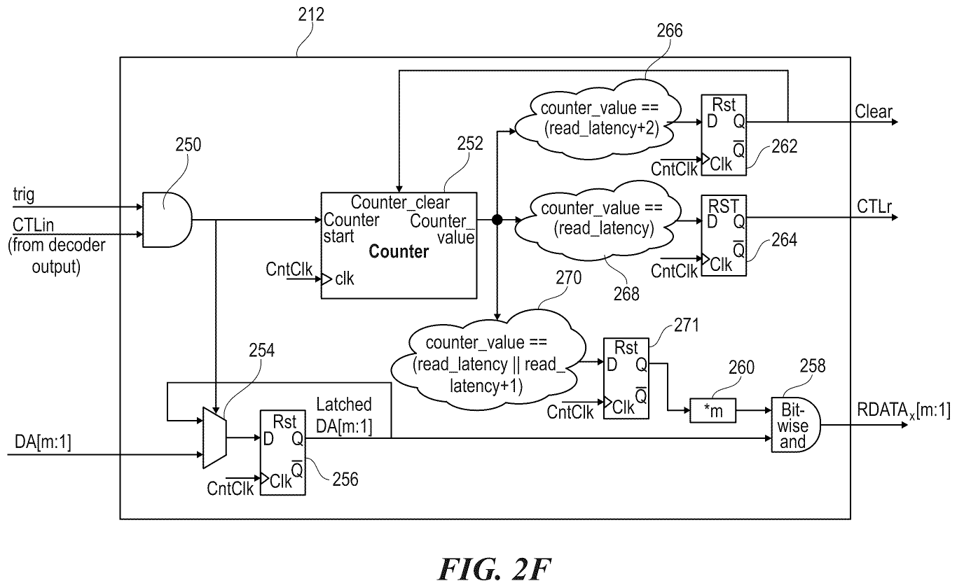

FIGS. 2A to 2E illustrate sub-blocks of memory IC 100 illustrated in FIG. 1B according to a particular embodiment implementation that utilizes four divided clocks and four per-read memory controllers 106. It should be understood that the implementation of FIGS. 2A to 2E is just one example of many possible implementations.

FIG. 2A depicts a block diagram of a counter select circuit 104 that can be used to implement counter select circuit 104 shown in FIG. 1B. The diagram shows multiple clock gating circuits 202 having control inputs that are coupled to ones of clock enable signals en[4:1] received through clock enable circuit 114 and corresponding ones of divided clock signal ck[4:1] received through clock divider 112. For example, the topmost clock gating circuit has its control input coupled to clock enable signal en[1] and its clock signal connected to corresponding divided clock signal ck[1]. During operation, each clock gating circuit 202 allows its clock input to pass to the output when its input is asserted. The output of each clock gating circuit 202 is connected to the input of OR gate 206, the output of which is connected to the input of n-bit shift register 204, where n=4 in this specific embodiment. In some embodiments, n-bit shift register 204 is configured to have a single bit active at any particular time, such that the output states of the shift register are 0001, 0010, 0100, and 1000. During operation, enable signal en[4:1] is active for one clock cycle of its corresponding divided clock ck[4:1], such that each clock gating circuit produces a single clock pulse in response to an incoming memory read command at memory interface 101. This single clock pulse is used to shift the contents of the shift register by one bit. For example, shift register 204 may have a repeating output sequence of 0001, 0010, 0100, and 1000.

Clock gating circuit 202 can be implemented using a series of logic gates that control the passage of the divided clock signals based on the state of the enable signals. Each clock gating circuit 202 may include an AND gate where one input is connected to the divided clock signal (ck[1], ck[2], ck[3], or ck[4]) and the other input receives the corresponding enable signal (en[1], en[2], en[3], or en[4]). When the enable signal for a particular clock gating circuit is asserted, the AND gate allows the divided clock signal to pass through; otherwise, the output of the AND gate is held low, effectively gating the clock signal. In some embodiments, clock gating circuit 202 may include deglitching circuitry, as known in the art. Alternatively, clock gating circuit 202 may be implemented using other logically equivalent circuits or other clock gating circuits known in the art.

Shift register 204 can be implemented as a series of flip-flops connected in a serial configuration, where the output of one flip-flop is connected to the input of the next flip-flop in the series. The shift register is designed to hold a binary value that represents the current selection of the per-read memory controller. The input to the shift register is connected to the output of OR gate 206, which combines the outputs from the clock gating circuits 202. The shift register advances its contents by one position with each clock pulse received from OR gate 206, cycling through a predefined sequence of binary states that correspond to the selection signals (sel[4:1]). The shift register may also include a reset input to initialize or reset the selection state to a valid state (e.g., 0001, 0010, 0100, or 1000) as part of the memory controller's initialization or error recovery process in some embodiments.

It should be understood that counter select circuit 104 in FIG. 2A is just one of many possible implementations of the counter select function. For example, in alternative embodiments, different logically equivalent logic topologies could be used to implement the same or similar function. In some embodiments, shift register 204 may be implemented using other circuits, such as a state machine. Such a state machine may include, for example, two state registers that store an encoded identification of the selected per-read memory controller (e.g., 00, 01, 10, and 11).

In further embodiments, counter select circuit 104 may be implemented using a circuit configured to perform an asynchronous search for a next available per-read memory controller.

FIG. 2B depicts a block diagram of a per-read memory controller 106 that could be used to implement each of memory controllers 106₂, 106₂ to 106ₙ shown in FIG. 1B. As shown, per-read memory 106 controller includes a control circuit 212, a clock select circuit 210, a control select circuit 214, and a trigger generator that includes an OR gate 218 and an AND gate 216.

The control circuit 212 within the per-read memory controller 106 is configured to manage the timing of read operations, including delaying the issuance of the control and data signals via a latency count that begins upon the assertion of trigger signal trig and is based on divided clock CntCLk provided to control circuit 212 via clock select circuit 210. The duration of the latency may be aligned with the memory array's requirements to ensure that the read data is available and can be output in a timely manner. Once the latency count is initiated, the control circuit 212 continues to track the passage of time until the count reaches its conclusion. At this point, the per-read memory controller 106 is signaled to commence the output of read operation signals, which include the read information data RDATAₓ and control signals CTLr.

In some embodiments, control circuit 212 is implemented using a digital counter, a latch for storing read information data DA[m:1] (to produce RDATAₓ), and other associated logic to produce control signals CTLr at the expiration of the latency count. Alternatively, signals RDATAₓ and/or CLTr may be output from control circuit 212 prior to or after the expiration of the latency count depending on the particular embodiment and its specifications. At the end of each read cycle, control circuit 212 asserts a signal Clear, which resets clock select circuit 210 and disables its clock output CntClk. This clear signal indicates that the per-read memory controller has finished its current task and is ready to be reset for the next dynamic assignment. In some embodiments, control circuit 212 may include a local command decoder.

Trigger signal trig, used to initiate the operation of control circuit 212, is generated using OR gate 218 and AND gate 216. When select signal selₓ is asserted (indicating that the present instance of per-read memory controller has been selected) and one of clock enable signals en[4:1] is received, AND gate 216 produces a trigger pulse that initiates operation of control circuit 212. It should be understood that the implementation using OR gate 218 and AND gate 216 is just one example of many possible circuits that could be used to generate trigger signal trig. In alternative embodiments, another circuit could be used; for example, a logically equivalent circuit or another type of circuit, such as a one-shot circuit. In further alternative embodiments, the start of operation may be affected by the result of decoding performed by decoder circuit 110 that produces control signal CTLin (see FIG. 1B).

In various embodiments, the read latency timing of per-read memory controller 106 may be adapted according to the particular result of decoder circuit 110 and/or a particular value of CTLin. For example, the read latency could be defined by a value written in a register. In some embodiments, this register value could be written by a user via a register write command.

Clock select circuit 210 is configured to forward the divided clock ck[4:1] that corresponds to its associated clock enable signal en[4:1] to output CntClk. In addition, clock select circuit 210 produces registered clock selection signals DivClkSel[4:1] for use by control select circuit 214, as is explained further below. Control select circuit 214 is configured to forward control signals CTLr onto one of four lines CTLₓ[4:1] that each corresponds to one of the four divided clock signals ck[4:1]. In various embodiments, control select circuit 214 is used to mask control outputs corresponding to non-used divided clocks to prevent downstream circuits, such as memory interface 118, from sampling the control signals using a non-used divided clock and to prevent timing issues. In an embodiment, read data information signals RDATAₓ may be sampled by a gated clock that is enabled by one of control lines CTL[4:1]. Alternatively, read data information signals RDATAₓ may be selected by applying an AND function to RDATAₓ and one of the control lines CTLₓ[4:1].

While the trigger generation circuit, including OR gate 216 and AND gate 216, clock select circuit 210, and control select circuit 214, are shown internal to per-read memory controller 106, it should be understood that in alternative embodiments, these blocks or their corresponding functions may be partitioned outside per-read memory controller 106 (e.g., other blocks within memory interface controller 102 shown in FIG. 1B).

FIG. 2C illustrates the clock select circuit 210 within the per-read memory controller 106. As mentioned above, the clock select circuit 210 dynamically selects the appropriate divided clock signal for each read operation of the per-read memory controller 106. For each respective pair of clock enable and divided clock signals, the clock select circuit 210 is composed of four clock selection subcircuits, each of which includes an AND gate 220, an OR gate 222, a register 224, and a clock gating circuit 226. During operation, the register 224 is set when the select signal and its respective clock enable signal en[x] are high, while its respective clock signal ck[x] is received on the clock input of register 224. This signal is then output as the respective divided clock enable signal DivClkSel[x], which is fed back to the D input of register 224 via OR gate 222. This feedback mechanism ensures that the respective divided clock enable signal (e.g., one of DivClkSel[4:1]) remains high for the duration of the memory read. The output of OR gate 222 also serves as the enable signal for the clock gating circuit 226. The output of the clock gating circuit 226 is then ORed by OR gate 228 to form the clock output signal CntClk, which is used to time the operations of the per-read memory controller 106.

When the per-read memory controller 106 is finished with a single memory read, control circuit 212 asserts the clear signal, which resets all registers 224, thereby disabling the clock signal CntClk and all divided clock selection signals DivClkSel[4:1]. While the clear signal is shown as resetting clock select circuit 210 in an asynchronous manner, it should be understood that in alternative embodiments, a synchronous reset could be used. In some embodiments, the internal latency counter within control circuit 212 is also reset.

FIG. 2D illustrates a block diagram of the control select circuit 214 situated within the per-read memory controller 106. This circuit is responsible for directing the control signals CTLr, which is generated by the control circuit 212, onto specific control lines CTLₓ[4:1]. Each of these control lines corresponds to one of the divided clock selection signals DivClkSel[4:1]. The control select circuit 214 is comprised of a series of AND gates 232, with each gate permitting the passage of the control signal CTLr to its output when the associated one of divided clock selection signals DivClkSel[4:1] is active. In embodiments in which the control signal CTLr includes multiple parallel signals, each AND gate 232 within FIG. 2D represents a group of individual AND gates, with each gate in the collection corresponding to one of the signals that constitute the control signal CTLr.

FIG. 2E depicts a block diagram of a dock enable circuit 114 shown in FIG. 1B. Clock enable circuit 114 includes an input register 242 that receives the user clock signal CK and the chip select signal CS from the memory interface (e.g., memory interface 101) and asserts an output signal on the Q output of the register when the chip select signal is high and the user clock signal is active. The output of register 242 is connected to the D inputs of registers 240 having clock inputs that are coupled to respective divided clock lines ck[4:1]. The Q outputs of registers 240 provide respective clock enable signals en[4:1]. In addition, the Q outputs of each register are coupled to the reset input of its second neighbor. For example, clock enable signal en[1] is connected to the reset input of the register 240 that produces clock enable signal en[3]; clock enable signal en[2] is connected to the reset input of the register 240 that produces clock enable signal en[4]; clock signal enable en[3] is connected to the reset input of the register 240 that produces clock enable signal en[1]; and clock enable signal en[4] is connected to the reset input of the register 240 that produces clock enable signal en[2]. In some embodiments (e.g., embodiments directed to LPDDR4 implementations that utilize two successive chip select pulses for a command) resetting the registers 240 in this manner allows for masking the second chip select CS pulse shown in the timing diagrams of FIGS. 1C and 1D. While the circuitry of clock enable circuit 114 shown in FIG. 2E is configured to operate with four divided clock, in alternative embodiments, the circuitry of clock enable circuit 114 shown in FIG. 2E may be adapted and/or modified to operate with a different number of divided clocks and different clock ratios.

FIG. 2F illustrates a schematic of control circuit 212 that could be used to implement control circuit 212, which is a component within per-read memory controller 106 shown in FIG. 2B. The control circuit 212 is responsible for managing the timing of read operations and generating the necessary control CTLr and read information data signals RDATAₓ based on the input trigger signal trig and the selected clock signal CntClk. Control circuit 212 includes a counter 252 that keeps track of the read latency period, comparison blocks 266, 268, and 270 that compare the counter value with predefined values or ranges, a multiplexer 254 that selects between the current and previously latched read information data, registers 256, 262, 264 and 271 that store various signals, a bit replicator block 260 that replicates the output of comparison block 270, and a bitwise AND gate 258 that combines the latched read information data with the replicated signal.

Counter 252 receives the trigger signal trig and the selected clock signal CntClk. The trigger signal trig, originating from the trigger generator (AND gate 216 and OR gate 218) in FIG. 2B, initiates the operation of counter 252. The selected clock signal CntClk, supplied by the clock select circuit 210 (FIG. 2B), acts as the dock input for counter 252. As shown, trigger signal trig is ANDed with signal CTLin (representing a read enable signal) generated by decoder 110 shown in FIG. 1B via and gate 250.

Comparison block 268 compares the output of counter 252 with a predefined read latency value. Thus, once the output of counter 252 reaches the predefined latency values, the output of register 264 (representing control signal CTLr) is asserted at the next rising edge of clock CntClk. Comparison block 270 compares the output of counter 252 with a sum of the predefined read latency value and one or more offset value (e.g., one and two). Accordingly, the output of comparison block 270 is asserted during the first and second cycles after the expiration of the latency count. In some embodiments, for example in embodiment in which RDATAₓ is set for more than one cycle, the output of comparison block 270 may be stored by register 271 that is clocked by clock CntClk to prevent glitching. The output of register 271 is replicated “m” times via bit replicator block 260, and the output of bit replicator block 260 is ANDed with latched read information data signals Latched DA[m:1] via bit-wise AND gate 258 to form output read information signal RDATAₓ[m:1].

Comparison block 266 compares the output of counter 252 with a value based on the predefined read latency value and an offset value of two. Thus, once the output of counter 252 reaches the predefined latency value plus two, the output of register 262 (representing clear signal Clear) is asserted at the next rising edge of clock CntClk. Signal Clear is used to reset counter 252 and per-read memory controller 106 at the end of each read.

It should be understood that the value for the read latency count can be programmable. Moreover, while comparison block 266 has an offset of two, and comparison block 270 has an offset of one or two with respect to the read latency value, it should be understood that other offsets may be used depending on the particular embodiment and its specifications in order to adjust the timing of read information data signal RDATAₓ[m:1], control signal CTLr, and clear signal Clear.

Multiplexer 254 receives the read information data DA[m:1] as one of its inputs, which is obtained from the user command and is previously latched by the data latching circuit 111 shown in FIG. 1B. The select input of multiplexer 254 is connected to register 256, which stores the previously latched value of DA[m:1]. The selection of multiplexer 254's output is controlled by the output of AND gate 250. The output of multiplexer 254 is connected to register 256, which latches the selected data on the rising edge of the selected clock signal CntClk. Thus, during operation, read information data is latched by the combination of multiplexer 254 and register 256 upon assertion of trigger signal trip when CTLin is asserted.

Counter 252 continues to operate until cleared by the Clear signal generated by comparison block 266 and register 262, which is asserted three cycles after the output of the counter has reached the value equal to read_latency. Once the read operation is complete and counter 252 is reset, the control circuit 212 becomes ready for the next read operation.

In alternative embodiments, control signal CTLr may include a plurality of signals instead of a single signal. Moreover, control signal(s) CTLr may be configured to have a particular sequence instead of being enabled for a single cycle. In some embodiments, the latched version of DA[m:1] output by register 256 may provide different selected bits in different times. In an alternative embodiment, for example an embodiment with a low read latency and/or low clock frequencies, the function of the counter is not used in a low read latency configuration, such that signals CTLr and RDATAₓ[m:1] are output directly. In some embodiments, one or more additional bits may be output at RDATAₓ that are not latched by register 256. In addition, in some embodiments, per-read memory controller 106 may be provided with configuration inputs that can be used to configure read latency, burst length and other parameters. Moreover, it should be appreciated other circuits

It should be appreciated that the circuits shown in FIGS. 2A to 2F are just a few examples of many possible circuits that could be used to implement memory control circuits according to embodiments. For example, in alternative embodiments, logically equivalent circuits or circuits that perform similar functions are those described herein may be used. The particular circuits, circuit topology and architecture may be adapted according to the needs and specifications a particular system.

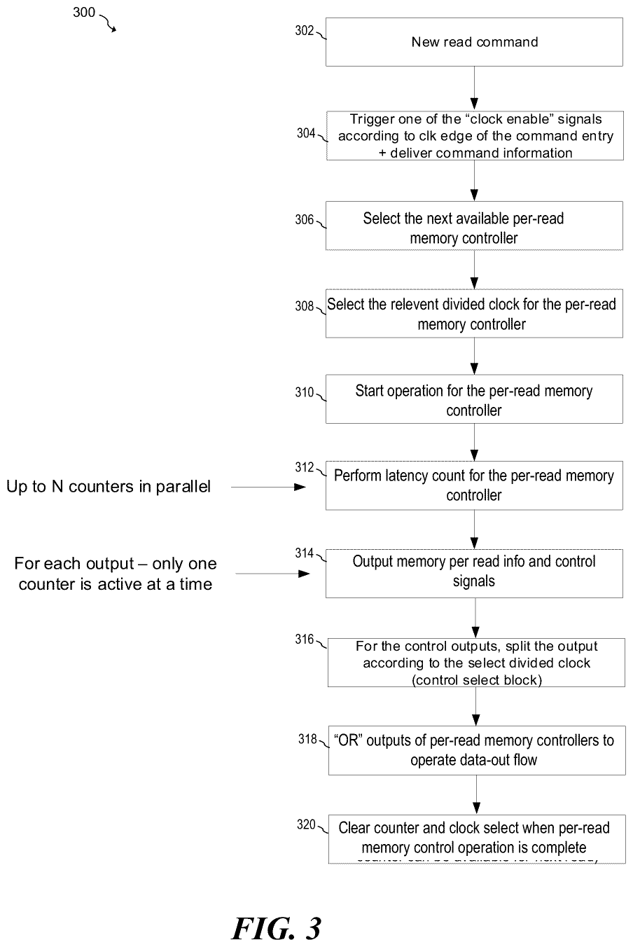

FIG. 3 depicts a flowchart of a method 300 for operating a memory controller according to embodiments, such as the memory IC according to FIG. 1B and/or the memory control circuit according to the specific implementation of FIGS. 2A to 2E. Method 300 begins with a read operation initiation step 302, which initiates the process of managing read operations. In some cases, the read operation initiation step 302 may involve receiving a read command from a user or a memory interface, such as memory interface 101.

Following the read operation initiation step 302, a clock enable signal (e.g., one of en[p:1]) is triggered according to the relationship between the incoming memory read command and the next divided clock. In some embodiments, this function is performed by the clock enable circuit 114 shown in FIG. 2E. In step 304, one of the clock enable signals en[p:1] is asserted. This step determines the timing of the command based on the clock edge. In some aspects, triggering the triggering clock enable signal may involve asserting a clock enable signal corresponding to a divided clock signal that has a phase corresponding to the received read command. In addition, command information is delivered to respective per-read memory controllers. In some embodiments, this delivery can include a command decoding step using decoder 110 shown in FIG. 1B to produce a decoded command signal CTLin that can represent, for example, a memory read, a register read, or other command.

In step 306, a per-read memory controller circuit is selected to determine which of the available per-read memory controllers 106 will handle the next read command. This step may be performed, for example, by the per-read memory controller selection circuit 104. In step 308, the relevant divided clock is selected for the counter selected in 306. This selection may be performed, for example, using the clock select circuit 210 shown in FIG. 2B and described above. In step 310, the operation for the per-read memory controller is started.

In step 312, the latency counter for the selected per-read memory controller is performed for a single read. In this step, the per-read memory controller 106 waits a predetermined latency time. Step 312 may be performed by multiple per-read memory controllers during operation. For example, in various embodiments, steps 302, 304,306, 308 and 310 may be repeated for new incoming memory commands on memory interface 101 while step 312 is being performed. Each new command will trigger step 312 again, thus step 312 can have up to N instances running in parallel, where N is the number of per-read memory controllers.

In step 314, the per-read memory controller outputs read information data and control signals, such as signals RDATAₓ and CTLₓ. In this step, each per-read memory controller is configured to output one set of read information data and control signals at a time. In step 316, the control outputs CTL are routed to separate outputs that each correspond to one of the divided clock signals. In some embodiments, step 316 may be implemented using the control select circuit 214 described above.

In step 318, the outputs (e.g., read information data and control signals) of each per-read memory controller is ORed together to combine the outputs to provide an output data flow. In some embodiments, these signals may be provided to facilitate different interface features, such as ECC address trapping, column redundancy replacement, GNG flow and support for internal register reads as discussed above. For example, for ECC address trapping, one or more of read information signals RDATA may provide the address for the address trapping, and one or more of control signals CTL may be used to trigger the trapping of the address. This ORing function may be implemented using the output combining circuit 108 described in FIG. 1B above.

In step 320, at the end of each single read operation, circuitry within the active per-read memory controller 106 is cleared in order to prepare it for future read operations. In some embodiments, this step is performed by resetting a latency counter within control circuit 212, resetting the clock select circuit 210, and resetting other relevant circuits, values and stored indication related to the completed memory operation. It should be understood that various steps in method 300 may be performed simultaneously when appropriate.

FIG. 4A illustrates a block diagram of a memory integrated circuit (IC) 400 according to an embodiment. Memory IC 400 includes an LPDDR interface 402, LPDDR output interface 402, a per-bank read trigger block 404, an address decoding block 405, a memory array 116, an interface block 406, an embodiment interface controller 102, general logic 407, and a memory array interface 418.

LPDDR input interface 402 is configured to receive various inputs such as chip select (CS), clock (CLK), and command/address (CA) signals from an external memory controller or host device. When a read command is received by the LPDDR I/O interface 402, the command and address information is sent to the per-bank read trigger block 404 and to interface block 406.

The per-bank read trigger block 404 translates the addresses received from the LPDDR I/O interface 402 into per-bank read addresses and read triggers for memory array 116. This block generates bank-specific read addresses and triggers based on the input address information. The per-bank read addresses and triggers are then provided to memory array 116 to initiate the read operation from the specified memory bank. In some embodiments, per-bank read-trigger block 404 performs a latching function under the control of interface block 406, and address decoding block 405 decodes the read address latched by per-bank read trigger block 404.

Memory array 116 includes of multiple memory banks 412, labeled as Bank 0 to Bank K−1 that store data to be retrieved during read operations. Each bank is associated with a read control circuit 410 that manages the read operation within its respective memory bank based on the read address and trigger provided by the per-bank read trigger block 404. The bank select mux 414 is responsible for selecting the data output from the appropriate memory bank for each read operation. It receives the read data outputs from the individual memory banks and selects the data from the bank corresponding to the current read operation. The selected data is then passed to memory array interface 418 for further processing and output.

General logic block 407 coupled to interface controller 102, memory array 116 and memory array interface 116 may include, but is not limited to various circuitry such as data pipes, a register array that supports register reading and writing, and logic configured to perform data error (ECC) calculations, data fixing, address trapping, column redundancy calculations, and data replacement. In some embodiments, the data pipes may reside within memory 116 instead of or in addition to within general logic block 407. Some of these features may also be supported by memory array interface 418. In some embodiments, such as embodiments in which memory array 116 is a flash memory array, data is latched for each bank 0 to K−1 after the data is sensed within the array.

Interface block 406 latches command signals received from LPDDR input interface circuit 402, divides an input clock and generates clock enable signals based on the relative timing between an incoming command and the present state of the divided clocks. As shown interface block 406 includes data latching block 111, clock divider 112, and clock enable circuit 114 described with respect to FIGS. 1B and 2E above.

Interface controller 102 (which may be implemented according to embodiments described above) receives the latched command signals, divided clocks, and clock enable signals from interface block 406 and generates the necessary control signals and read information for the memory array interface 418. Interface controller 102 incorporates the per-read memory controllers and associated circuits that enable efficient parallel processing of multiple read operations as described according to embodiments above. In some embodiments, depending on the particular specific implementation, interface controller 102 may send control and/or information data (e.g. CTL/RDATA) to LPDDR output interface 408. In some embodiments, this control and/or information data may be used to control memory array 116, for example to select one of memory banks 0 to K−1.

Memory array interface 418 has a similar overall function as memory array interface 118 described earlier in the specification. It acts as an intermediary between interface controller 102 and memory array 116. In an embodiment, memory array interface 418 receives the control signals and data from interface controller 102 and manages the data flow from the memory array to LPDDR output interface 408 for outputting the read data. LPDDR output interface 408 transfers read data signals from memory array interface 418 to the outside world, for example, via signals DS and DQS.

During operation, when a read command is received by the LPDDR input interface 402, the address information is latched by data latching block 111, and sent to the per-bank read trigger block 404, which generates the per-bank read addresses and triggers for memory array 116.

The read command is also latched by data latching block 111 within interface block 406 and passed to interface controller 102. Interface controller 102 processes the read command using its per-read memory controllers and generates the necessary control signals and data to wait for data from memory 116 to be ready during a read latency and then controlling the data output from memory 116. For example, in some embodiments, interface controller may control bank select mux 414. Interface controller 102 may also control other functions such as a register read or ECC functions (in addition to or in conjunction with general logic 407) for memory array interface 418. Memory array interface 418 receives memory data from memory array 116 via general logic 407 from the memory bank selected by bank select mux 414. The read data is then outputted through memory array interface 418 and LPDDR output interface 408 to the external host or memory controller.

The architecture of memory IC 400 advantageously enables efficient parallel processing of multiple read operations by utilizing the per-read memory controllers within interface controller 102. This allows for improved performance and reduced latency compared to memory architectures that process read operations sequentially.

FIG. 4B illustrates a block diagram of a memory system 450 according to an embodiment. Memory system 450 includes memory IC 452 coupled to a host 451. Memory IC 452 includes a lower speed physical layer (PHY) for slower speed memory interface operations, such as writing to memory, and a separate high-speed PHY 458 for high-speed memory reads and other commands such as register read and write comments and program/erase commands. High-speed PHY 458 incorporates PHY logical layer 462 that includes an embodiment memory interface controller 102, a clock divider 112, and a PHY custom analog layer 460. Memory IC 452 also includes a memory array 116 for storing data and general logic block 456.

Interface bits exchanged between host 451 and lower speed PHY 454 may include, for example, SPI read commands. Types of read commands supported by memory IC 452 may include, but are not limited, for example, a flash read command according to LPDDR interface standards, an array read command that uses a same LPDDR command sequence as a standard DRAM to support existing DRAM controllers, a configuration register read in order to read the contents of on-chip registers, and read training to perform a read of known patterns so that host 451 can verify data.

Lower speed PHY 454 may be implemented, for example, using analog and digital circuits designed for the specific interface standard such as (but not limited to) a serial peripheral interface (SPI).

General logic block 456 performs various memory control functions such as program/erase operations, address decoding, read control, and error correction (ECC).

an address decoder for generating memory addresses, read/write control logic for controlling memory read and write operations, and ECC circuits for detecting and correcting errors in stored data. General logic block 456 can be implemented using digital logic circuits, state machines, and memory circuits such as SRAMs. In some embodiments, General logic block 456 may include memory array interface 418 and general logic 407 described according to embodiments above.

High speed PHY 458 manages the physical layer interface for high-speed memory access, and includes clock divider 112, memory interface controller 102, and PHY custom analog layer 460. PHY 458 may include a command decoder for decoding memory access commands,

It can be implemented using a combination of analog and digital circuits designed for high-speed operation. In some embodiments, higher speed PHY 458 implemented an LPDDR interface, such as an LPDDR4 interface.

Clock divider 112 divides a user clock received from host 451 to generate divided clocks with different phases for use by memory interface controller 102. Clock divider can be implemented using a flip-flop-based divider, or other suitable clock divider circuitry.

As shown, PHY logical layer 462 includes embodiment memory interface controller 102 described according to embodiments above that includes per-read memory controllers 106 for parallel processing of read commands. Controller 102 can be implemented using digital logic circuits, state machines, and other circuits as described earlier.

PHY custom analog layer 460 is a custom analog circuit layer for the high-speed PHY interface 458. It can include circuits such as receivers, drivers, voltage and current reference generators, and comparators that are specifically designed for the high-speed memory interface. The analog layer 460 is designed to interface with the digital logic in PHY logical layer 462 and memory interface controller 102. The analog layer 460 may include custom analog circuitry that may support the high frequency of a fast user clock which might not be supported by other logic circuitry.

Memory array 116 is the memory array block for storing data, as described in embodiments above. In some embodiments, memory 116 is a non-volatile memory, such as, but not limited to flash memory, erasable read only memory (EPROM), electrically erasable read only memory, resistive random-access memory (RRAM), or magentoresistive RAM. Alternatively, memory array 116 may be a volatile memory, such as DRAM or SRAM.

It should be appreciated that the memory embodiments of FIGS. 4A and 4B are just two of many possible memory systems that incorporate a memory interface controller according to embodiments of the present invention.

Embodiments of the present invention are summarized here. Other embodiments can also be understood from the entirety of the specification and the claims filed herein.

Example 1. A circuit, including: a plurality of per-read memory controllers, each of the plurality of per-read memory controllers configured to output a set of read operation signals based on a dynamically selected divided clock signal of a plurality of divided clock signals, where each divided clock signal of the plurality of divided clock signals has a different phase; a memory controller selection circuit configured to sequentially select a per-read memory controller from the plurality of per-read memory controllers for a single read operation, where a selected per-read memory controller in a first read operation is different from a selected per-read memory controller in a subsequent read operation; and an output combining circuit coupled to outputs of the plurality of per-read memory controllers.

Example 2. The circuit of example 1, where the read operation signals includes read information signals and control signals.

Example 3. The circuit of example 2, where the control signals are configured to control a read-out of data from a memory array.

Example 4. The circuit of any one of examples 1 to 3, where each of the plurality of per-read memory controllers is configured to: output the set of read operation signals in response to an assertion of a trigger signal; and wait a predetermined latency time after the assertion of the trigger signal prior to output the set of read operation signals.

Example 5. The circuit of any one of examples 1 to 4, where each of the plurality of per-read memory controllers further includes: a memory control circuit; and a clock selection circuit configured to: perform a dynamic selection of the dynamically selected divided clock signal from among the plurality of divided clock signals based on a clock enable signal corresponding to a phase of the dynamically selected divided clock signal; and output the dynamically selected divided clock signal to the memory control circuit.

Example 6. The circuit of example 5, where: the memory control circuit is configured to cause the clock selection circuit to stop outputting the dynamically selected divided clock signal upon finishing outputting the set of read operation signals.

Example 7. The circuit of any one of examples 1 to 6, further including a clock enable circuit configured to: receive a memory read command from a memory bus; and assert one of a plurality of enable signals corresponding to one of the plurality of the divided clock signals having a phase corresponding to the received memory read command.

Example 8. The circuit of example 7, where each of the plurality of per-read memory controllers is further configured to dynamically select the one of the plurality of the divided clock signals corresponding to the asserted one of the plurality of enable signals.

Example 9. The circuit of example 7 or 8, further including a clock divider configured to: receive a clock at a memory interface; and divide a received clock to produce the plurality of the divided clock signals.

Example 10. The circuit of any one of examples 1 to 9, further including a command decoder configured to: receive data from a memory interface; and generate the set of read operation signals based on the received data.

Example 11. The circuit of example 10, where the memory interface is a LPDDR4 interface.

Example 12. The circuit of any one of examples 1 to 11, where the memory controller selection circuit includes a shift register, where each bit of the shift register corresponds to a per-read memory controller of the plurality of per-read memory controllers.

Example 13. A method of operating a memory, the method including; selecting a per-read memory controller from a plurality of per-read memory controllers for a single read operation where a selected per-read memory controller in a first read operation is different from a selected per-read memory controller in an immediately subsequent read operation; and outputting a set of read operation signals by the selected per-read memory controller, the set of read operation signals being timed according to a dynamically selected clock signal of a plurality of divided clock signals.

Example 14. The method of example 13, where: outputting the set of read operation signals by the selected per-read memory controller is performed in response to an assertion of a trigger signal; and the method further includes waiting a predetermined latency time after the assertion of the trigger signal prior to outputting the set of read operation signals.

Example 15. The method of example 13 or 14, further including receiving a memory read command from a memory bus.

Example 16. The method of example 15, further including generating, by the selected per-read memory controller, the set of read operation signals based on the received memory read command.

Example 17. The method of example 15 or 16, further including: asserting one of a plurality of enable signals corresponding to one of the plurality of the divided clock signals having a phase corresponding to the received memory read command; and dynamically selecting, by the selected per-read memory controller, the one of the plurality of the divided clock signals having the phase corresponding to the received memory read command.

Example 18. The method of example 17, further including: asserting a select signal corresponding to the selected per-read memory controller; and asserting a trigger signal based on the asserted select signal and the asserted one of the plurality of enable signals.

Example 19. The method of any one of examples 13 to 18, further including providing the at least a portion of the set of read operation signals to a memory array.

Example 20. The method of any one of examples 13 to 19, further including controlling a readout of a memory array using the at least a portion of the set of the read operation signals.

Example 21. The method of any one of examples 13 to 20, where the memory includes a non-volatile memory array.

Example 22. A system, including: a memory array; a memory interface configured to be coupled to a memory bus; a clock divider having an input coupled to a clock signal input of the memory interface and outputs configured to provide a plurality of divided clock signals having different phases; a clock enable circuit configured to receive a selection signal from the memory interface and assert one of a plurality of enable signals corresponding to one of the plurality of the divided clock signals having a phase corresponding to the received selection signal; a plurality of per-read memory controllers having data inputs coupled to the memory interface, clock inputs coupled to outputs of the clock divider, and enable inputs coupled to the plurality of enable signals, each of the plurality of per-read memory controllers configured to output a set of read operation signals based on data provided to the memory interface, where the set of read operation signals is timed according to the one of the plurality of divided clock signals having the phase corresponding to the received selection signals; a memory controller selection circuit configured to sequentially select a per-read memory controller from the plurality of per-read memory controllers for a single read operation, where a selected per-read memory controller in a first read operation is different from a selected per-read memory controller in a subsequent read operation; and a combining circuit having inputs coupled to outputs of the plurality of per-read memory controllers, and an output coupled to the memory array.

Example 23. The system of example 22, where the memory array includes a non-volatile memory array.

Example 24. The system of example 22 or 23, where the memory interface includes a LPDDR4 interface.

While this invention has been described with reference to illustrative embodiments, this description is not intended to be construed in a limiting sense. Various modifications and combinations of the illustrative embodiments, as well as other embodiments of the invention, will be apparent to persons skilled in the art upon reference to the description. It is therefore intended that the appended claims encompass any such modifications or embodiments.

What is claimed is:

1. A circuit, comprising:
a plurality of per-read memory controllers, each of the plurality of per-read memory controllers configured to output a set of read operation signals based on a dynamically selected divided clock signal of a plurality of divided clock signals, wherein each divided clock signal of the plurality of divided clock signals has a different phase;
a memory controller selection circuit configured to sequentially select a per-read memory controller from the plurality of per-read memory controllers for a single read operation, wherein a selected per-read memory controller in a first read operation is different from a selected per-read memory controller in a subsequent read operation; and
an output combining circuit coupled to outputs of the plurality of per-read memory controllers.

2. The circuit of claim 1, wherein the set of read operation signals comprises read information signals and control signals.

3. The circuit of claim 2, wherein the control signals are configured to control a read-out of data from a memory array.

4. The circuit of claim 1, wherein each of the plurality of per-read memory controllers is configured to:
output the set of read operation signals in response to an assertion of a trigger signal; and
wait a predetermined latency time after the assertion of the trigger signal prior to output the set of read operation signals.

5. The circuit of claim 1, wherein each of the plurality of per-read memory controllers further comprises:
a memory control circuit; and
a clock selection circuit configured to:
perform a dynamic selection of the dynamically selected divided clock signal from among the plurality of divided clock signals based on a clock enable signal corresponding to a phase of the dynamically selected divided clock signal; and
output the dynamically selected divided clock signal to the memory control circuit.

6. The circuit of claim 5, wherein:
the memory control circuit is configured to cause the clock selection circuit to stop outputting the dynamically selected divided clock signal upon finishing outputting the set of read operation signals.

7. The circuit of claim 1, further comprising a clock enable circuit configured to:
receive a memory read command from a memory bus; and
assert one of a plurality of enable signals corresponding to one of the plurality of the divided clock signals having a phase corresponding to the received memory read command.

8. The circuit of claim 7, wherein each of the plurality of per-read memory controllers is further configured to dynamically select the one of the plurality of the divided clock signals corresponding to the asserted one of the plurality of enable signals.

9. The circuit of claim 7, further comprising a clock divider configured to:
receive a clock at a memory interface; and
divide a received clock to produce the plurality of the divided clock signals.

10. The circuit of claim 1, further comprising a command decoder configured to:
receive data from a memory interface; and
generate the set of read operation signals based on the received data.

11. The circuit of claim 10, wherein the memory interface is a LPDDR4 interface.

12. The circuit of claim 1, wherein the memory controller selection circuit comprises a shift register, wherein each bit of the shift register corresponds to a per-read memory controller of the plurality of per-read memory controllers.

13. A method of operating a memory, the method comprising;
selecting a per-read memory controller from a plurality of per-read memory controllers for a single read operation wherein a selected per-read memory controller in a first read operation is different from a selected per-read memory controller in an immediately subsequent read operation; and
outputting a set of read operation signals by the selected per-read memory controller, the set of read operation signals being timed according to a dynamically selected clock signal of a plurality of divided clock signals.

14. The method of claim 13, wherein:
outputting the set of read operation signals by the selected per-read memory controller is performed in response to an assertion of a trigger signal; and
the method further comprises waiting a predetermined latency time after the assertion of the trigger signal prior to outputting the set of read operation signals.

15. The method of claim 13, further comprising receiving a memory read command from a memory bus.

16. The method of claim 15, further comprising generating, by the selected per-read memory controller, the set of read operation signals based on the received memory read command.

17. The method of claim 15, further comprising:
asserting one of a plurality of enable signals corresponding to one of the plurality of the divided clock signals having a phase corresponding to the received memory read command; and
dynamically selecting, by the selected per-read memory controller, the one of the plurality of the divided clock signals having the phase corresponding to the received memory read command.

18. The method of claim 17, further comprising:
asserting a select signal corresponding to the selected per-read memory controller; and
asserting a trigger signal based on the asserted select signal and the asserted one of the plurality of enable signals.

19. The method of claim 13, further comprising providing the at least a portion of the set of read operation signals to a memory array.

20. The method of claim 13, further comprising controlling a readout of a memory array using the at least a portion of the set of the read operation signals.

21. The method of claim 20, wherein the memory comprises a non-volatile memory array.

22. A system, comprising:
a memory array;
a memory interface configured to be coupled to a memory bus;
a clock divider having an input coupled to a clock signal input of the memory interface and outputs configured to provide a plurality of divided clock signals having different phases;
a clock enable circuit configured to receive a selection signal from the memory interface and assert one of a plurality of enable signals corresponding to one of the plurality of the divided clock signals having a phase corresponding to the received selection signal;
a plurality of per-read memory controllers having data inputs coupled to the memory interface, clock inputs coupled to outputs of the clock divider, and enable inputs coupled to the plurality of enable signals, each of the plurality of per-read memory controllers configured to output a set of read operation signals based on data provided to the memory interface, wherein the set of read operation signals is timed according to the one of the plurality of divided clock signals having the phase corresponding to the received selection signals;
a memory controller selection circuit configured to sequentially select a per-read memory controller from the plurality of per-read memory controllers for a single read operation, wherein a selected per-read memory controller in a first read operation is different from a selected per-read memory controller in a subsequent read operation; and
a combining circuit having inputs coupled to outputs of the plurality of per-read memory controllers, and an output coupled to the memory array.

23. The system of claim 22, wherein the memory array comprises a non-volatile memory array.

24. The system of claim 22, wherein the memory interface comprises a LPDDR4 interface.
